(19) United States
(12) Patent Application Publication
(10) Pub. No.: US 2021/0165601 A1
(43) Pub. Date: Jun. 3, 2021

(54) DATA COMPRESSION CIRCUIT, MEMORY DEVICE AND IC TEST DEVICE AND METHOD

(71) Applicant: Changxin Memory Technologies, Inc., Hefei (CN)

(72) Inventor: Chia-Chi HSU, Hefei (CN)

(21) Appl. No.: 17/166,751

(22) Filed: Feb. 3, 2021

Related U.S. Application Data
(63) Continuation of application No. PCT/CN2019/099432, filed on Aug. 6, 2019.

(30) Foreign Application Priority Data
Aug. 28, 2018 (CN) 201810986599.9
Aug. 28, 2018 (CN) 201821397381.1

(51) Int. Cl. G06F 3/06

(52) U.S. Cl. CPC G06F 3/0655; G06F 3/0673; G06F 3/0653; G06F 3/0604

(57) ABSTRACT

A data compression circuit, a memory device and an integrated circuit (IC) test device and method are disclosed. The data compression circuit includes a data-writing circuit and a data-reading circuit. The data-writing circuit includes a first input interface, a plurality of first output interfaces and a data-writing module, and the data-reading circuit includes a plurality of second input interfaces, a second output interface and a data-reading module. The data-writing module may be configured to write out-going data into an IC, and the data-reading module may be configured to read incoming data from the IC and generate a test result based on the incoming data. In this data compression circuit, the combination of the data-writing circuit and the data-reading circuit may bring a multi-fold increase in the number of ICs that can be tested simultaneously, which substantially improves the test efficiency and reduces the cost of a test.

### CROSS-REFERENCE TO RELATED APPLICATIONS

This application is a continuation application of International Patent Application No. PCT/CN2019/099432, filed on Aug. 6, 2019, which is based on and claims priority of the Chinese Patent Applications No. 201810986599.9 and 201821397381.1, both filed on Aug. 28, 2018. The above-referenced applications are incorporated herein by reference in their entirety.

### TECHNICAL FIELD

This invention relates generally to the field of electrical technology and, more specifically, to data compression circuit, memory device and integrated circuit (IC) test device and method.

### BACKGROUND

The semiconductor industry has experienced rapid growth with the advancements in technologies. IC testing is an essential component of the IC supply chain, and various automatic IC testers have been developed for large-scale centralized IC testing.

Since an automatic IC tester usually has a fixed number of test channels, the number of ICs that can be tested simultaneously is limited. For example, a 1024-channel automatic IC tester may simultaneously test 128 8-pin IC dies or 64 16-pin IC dies. Thus, the number of IC dies that can be simultaneously tested is limited by the number of test channels, which leads to low test efficiency. Therefore, there is an urgent need to increase the number of ICs that can be simultaneously tested and hence increase the test efficiency.

The information disclosed in this Background section is only for facilitating the understanding of the background of the invention and therefore may contain information that does not form the prior art already known to a person of ordinary skill in the art.

### SUMMARY

To address the limitations of conventional IC test devices and methods described above, this disclosure presents a data compression circuit, a memory device, and an IC test device and method that may bring a multi-fold increase in the number of ICs that can be simultaneously tested, which substantially improves the test efficiency and reduces the cost of a test.

One aspect of this disclosure is directed to an electronic device comprising an integrated circuit (IC) and a data compression circuit for testing the IC. The data compression circuit may include a data-writing circuit and a data-reading circuit. The data-writing circuit may include a first input interface for receiving test data, a plurality of first output interfaces coupled to the IC, and a data-writing module configured to write first data derived from the test data into the IC via the plurality of first output interfaces.

The data-reading circuit may include a plurality of second input interfaces coupled to the IC, a second output interface coupled to a sender of the test data, and a data-reading module configured to read second data from the IC via the plurality of second input interfaces, generate a test result based on the second data, and send the test result to the sender of the test data via the second output interface.

In some embodiments, in the foregoing device, the plurality of first output interfaces and the plurality of second input interfaces may be both connected to a plurality of data channels of the IC.

In some embodiments, in the foregoing device, the plurality of data channels may comprise two data channels. The data-writing module may be configured to write the first data into the two data channels via the first output interfaces, and the first data written into each of the two data channels may be identical. The data-reading module may be configured to read the second data from the two data channels via the second input interfaces and determine whether the second data read from the two data channels are identical.

In some embodiments, in the foregoing device, the data-reading module may include a plurality of XNOR gates each having input terminals coupled to the plurality of second input interfaces, and one or more AND gates each having input terminals coupled to output terminals of the plurality of XNOR gates and an output terminal coupled to the second output interface.

In some embodiments, in the foregoing device, the test result may be pass if an output signal of the one or more AND gates is a high level.

In some embodiments, in the foregoing device, the test result may be fail is the second data read from the two data channels are different.

In some embodiments, in the foregoing device, a number of the first output interfaces may be equal to a number of the second input interfaces.

In some embodiments, in the foregoing device, the data-writing module may include one or more demultiplexers.

In some embodiments, in the foregoing device, the data-reading module may include one or more multiplexers.

In some embodiments, in the foregoing device, the IC may be a dynamic random access memory (DRAM).

Another aspect of this disclosure is directed to an IC testing method. The IC testing method may include receiving test data via a first input interface, writing first data derived from the test data into an IC via a plurality of first output interfaces, reading second data from the IC via a plurality of second input interfaces, generating a test result based on the second data, and sending the test result to a sender of the test data via a second output interface.

In some embodiments, in the foregoing method, the plurality of first output interfaces and the plurality of second input interfaces may be both connected to a plurality of data channels of the IC.

In some embodiments, in the foregoing method, the plurality of data channels may comprise two data channels. The writing first data derived from the test data into an IC via a plurality of first output interfaces may include: writing the first data into the two data channels via the first output interfaces, wherein the first data written into each of the two data channels are identical. The reading second data from the IC via a plurality of second input interfaces may include: reading the second data from the two data channels via the second input interfaces, and determining whether the second data read from the two data channels are identical.

In some embodiments, in the foregoing method, the plurality of second input interfaces may be coupled to input terminals of a plurality of XNOR gates, the second output interface may be coupled to an output terminal of one or more AND gates. Output terminals of the plurality of the XNOR gates may be coupled to input terminals of the one or more AND gates.

In some embodiments, in the foregoing method, the test result may be pass if an output signal of the one or more AND gates is a high level.

In some embodiments, in the foregoing method, the test result may be fail if the second data read from the two data channels are different.

In some embodiments, in the foregoing method, a number of the first output interfaces may be equal to a number of the second input interfaces.

In some embodiments, in the foregoing method, the first input interface may be coupled to an input of one or more demultiplexers, and the plurality of first output interfaces may be coupled to outputs of the one or more demultiplexers.

In some embodiments, in the foregoing method, the plurality of second input interfaces may be coupled to inputs of one or more multiplexers, and the second output interface may be coupled to an output of the one or more multiplexers.

In some embodiments, in the foregoing method, the IC may be a DRAM.

In the data compression circuits according to the embodiments of this disclosure, the combination of the data-writing circuit and data-reading circuit allows simultaneous testing of a plurality of ICs as well as a plurality of data channels or data transmission nodes therein. That may address a limitation of conventional techniques that one IC may occupy multiple test channels of an automatic IC tester. Thus, for the automatic IC tester which is expensive and has a limited number of test channels, the data compression circuits according to the embodiments of this disclosure may bring a multi-fold increase in the number of ICs that can be simultaneously tested, which may substantially increase the test efficiency and reduce the cost of a test.

### BRIEF DESCRIPTION OF THE DRAWINGS

The accompanying drawings, which are incorporated in and constitute a part of the description, illustrate embodiments in accordance with this disclosure and, together with the description, serve to explain the disclosed inventive concept. It is apparent that these drawings present only some embodiments of the present inventive concept and persons of ordinary skill in the art may obtain drawings of other embodiments from them without creative effort.

FIG. 1 is a block diagram of a data compression circuit in accordance with one embodiment of this disclosure.

FIG. 2 is a block diagram of a data-writing circuit of a data compression circuit in accordance with one embodiment of this disclosure.

FIG. 3 is a block diagram of a data-reading circuit of a data compression circuit in accordance with one embodiment of this disclosure.

FIG. 4A is a block diagram showing an application of a data-writing circuit of a data compression circuit in accordance with one embodiment of this disclosure.

FIG. 4B is a block diagram showing an application of a data-reading circuit of a data compression circuit in accordance with one embodiment of this disclosure.

FIG. 5A is a block diagram showing an application of a data-writing circuit of a data compression circuit in accordance with one embodiment of this disclosure

FIG. 5B is a block diagram showing an application of a data-reading circuit of a data compression circuit in accordance with one embodiment of this disclosure.

FIG. 6A is a block diagram showing an application of a data-writing circuit of a data compression circuit in accordance with one embodiment of this disclosure.

FIG. 6B is a block diagram showing an application of a data-reading circuit of a data compression circuit in accordance with one embodiment of this disclosure.

FIG. 7 is a flowchart of an IC test method in accordance with one embodiment of this disclosure.

### LIST OF REFERENCE NUMERALS IN DRAWINGS

110 Data Compression Circuit
111 Data-writing Circuit
112 Data-reading Circuit
120 Automatic IC Tester
130 For-Test ICs
210 Data-writing Module
220 First Input Interface
230 First Output Interface
310 Data-reading Module
320 Second Input Interface
330 Second Output Interface

### DETAILED DESCRIPTION OF THE EMBODIMENTS

Exemplary embodiments will now be described in details with reference to the accompanying drawings. However, these exemplary embodiments can be implemented in many forms and should not be construed as being limited to those set forth herein. Rather, these embodiments are presented to provide a full and thorough understanding of the present inventive concept and to fully convey the concepts of the embodiments to others skilled in the art. In the drawings, like reference numerals may indicate the same or analogous elements, and duplicate detailed description thereof will thus be omitted.

Although relative terms such as “upper” and “lower” may be used herein to describe a spatial relationship of one component to another in a device shown in the drawings, they are used merely for the purpose of easy description based on, for example, the exemplary orientation depicted in the drawings. It is to be understood that if the illustrated device is turned upside down, then the component described as being “upper” may now be a “lower” component. When a certain structure is described as being “on” another structure, it is possible that the specific structure is either integrally formed on the other structure or disposed thereon “directly” or “indirectly” via an intervening structure.

As used herein, the terms “a”, “an” “the”, “said” and “at least one” are intended to mean that there are one or more elements/components. As used herein, the terms “including” and “having” are intended to be used in an open-ended sense to mean that there are possibly other element(s)/component(s) apart from the listed element(s)/component(s). The terms “first”, “second”, “third”, etc. as used herein may refer to labels rather than a quantitative limitation upon the amount of the mentioned items.

In one embodiment of this disclosure, a data compression circuit for testing an integrated circuit (IC) is provided. The data compression circuit may be an IC sub-block packaged in a test chip together with the IC, or a separately-packaged standalone IC unit to be connected to a test chip and an automatic IC tester, or a functional unit incorporated within an automatic IC tester and coupled to a test channel thereof. Detailed configuration of the data compression circuit of this disclosure is not limited in this regard.

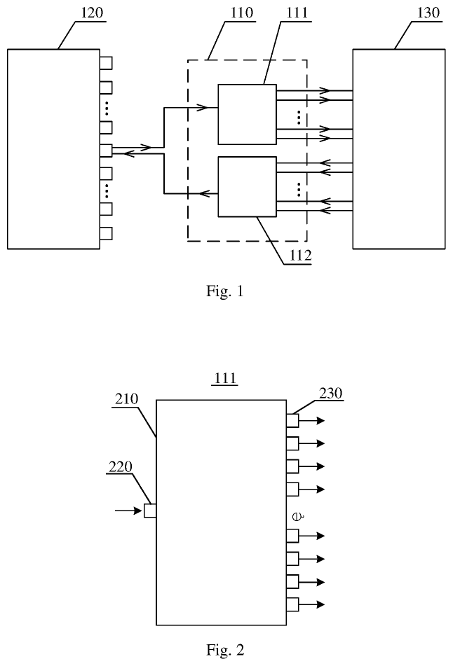

Referring to FIG. 1, to test an IC 130, the data compression circuit 110 according to one embodiment of this disclosure may be arranged between an automatic IC tester 120 and the IC 130. The data compression circuit 110 may include a data-writing circuit 111 and a data-reading circuit 112. The automatic IC tester 120 may be configured to write test data into the IC 130 through the data-writing circuit 111, read a test result from the IC 130 through the data-reading circuit 112, and determine whether the IC 130 passes the test based on the test result. The automatic IC tester 120 may have a plurality of test channels and thus can test a plurality of ICs 130 simultaneously. The IC 130 may be an unpackaged complete IC with a plurality of data channels, or a packaged standalone chip with a plurality of data pins, or an IC sub-block with a plurality of data channels incorporated within a chip. Detail composition of the IC 130 is not limited in any particular way in this regard in this embodiment.

Referring to FIG. 2, the data-writing circuit 111 may essentially include a data-writing module 210, a first input interface 220 and a plurality of first output interfaces 230.

The first input interface 220 may serve as an interface which allows the automatic IC tester 120 to input data into the data compression circuit 110 and may be configured to receive test data for the IC 130. The test data may be either directly received from the automatic IC tester 120, or indirectly processed or transmitted by other means. The automatic IC tester 120 may provide a desired test result associated with the IC 130 and the test data, which may be compared with an actual test result returned from the IC 130 to determine whether the IC 130 has passed a test.

The first output interfaces 230 may be coupled to the IC 130 and may act as an interface allowing the data compression circuit 110 to write out-going data into the IC 130. The out-going data written into the IC 130 via the first output interfaces 230 may be either exactly the same as the test data received via the first input interface 220, or related to but not identical to the test data received via the first input interface 220. Each of the first output interfaces 230 may write identical or different out-going data into the IC 130. The out-going data to be written may be selected and distributed depending on the test requirements. The first output interfaces 230 may be coupled to the respective data channels of the IC 130 so as to allow writing of the out-going data into the IC 130 via these data channels. The first output interfaces 230 may also be coupled to respective data transmission nodes within the IC 130. In this case, the data-writing module 210 may write out-going data into the IC 130 via the respective data transmission nodes so that a test on individual data transmission node becomes possible. Other than the data channels and the data transmission nodes, the first output interfaces 230 may also be coupled to other locations in the IC 130, and this disclosure is not limited in any particular way in this regard.

The data-writing module 210 may be configured to perform data processing based on the test data received via the first input interface 220 and write the processed data chunks resulting from the data processing into the IC 130 via the respective first output interfaces 230. Therefore, the data-writing module 210 may be considered as a single-input multiple-output (SIMO) device capable of receiving the test data from one test channel of the automatic IC tester 120 and synchronously or asynchronously writing multiple data chunks into the IC 130. The data-writing module 210 may be implemented by, for example, a data distributor, a demultiplexer (DEMUX) or any other electronic component or combination of electronic components capable of data allocation or data splitting, and this disclosure is not limited in any particular way in this regard.

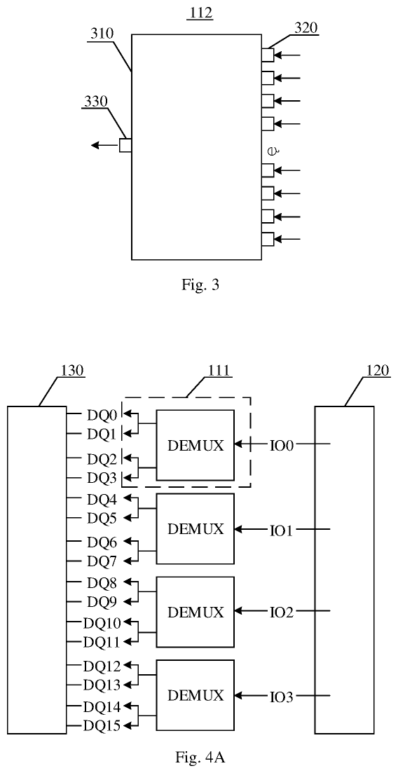

Referring to FIG. 3, the data-reading circuit 112 may essentially include a data-reading module 310, a plurality of second input interfaces 320 and a second output interface 330.

The second input interfaces 320 may be coupled to the IC 130 and may function as interfaces allowing the data compression circuit 110 to read incoming data from the IC 130. The second input interfaces 320 may read the incoming data from the IC 130 synchronously or asynchronously, and the incoming data may serve as a basis for generating a test result. Similar to the first output interfaces 230, the second input interfaces 320 may be coupled to the respective data channels of the IC 130 so as to allow reading of the incoming data via these data channels. The second input interfaces 320 may also be coupled to the respective data transmission nodes within the IC 130 so as to allow reading of the incoming data from these data transmission nodes. Other than the data channels and the data transmission nodes, the second input interfaces 320 may also be coupled to other locations in the IC 130, and this disclosure is not limited in any particular way in this regard.

The second output interface 330 may be coupled to a sender from which the data compression circuit 110 receives the test data, and a test result may be returned to the sender. In some embodiments, the sender may be the automatic IC tester 120. The test result may be directly or indirectly transmitted to the automatic IC tester 120, or be processed by other means. The automatic IC tester 120 may be configured to compare the returned test result with the desired test result and thereby determine whether the IC 130 has passed the test.

The data-reading module 310 may be configured to read the incoming data from the IC 130 via the plurality of second input interfaces 320, generate the test result based on the incoming data and send the test result to the sender of the test data via the second output interface 330. Therefore, the data-reading module 310 may be considered as a multiple-input single-output (MISO) device capable of utilizing only one test channel of the automatic IC tester 120 to read data via the plurality of data channels or data transmission nodes of the IC 130, and to obtain a test result to complete a test on the IC. The data-reading module 310 may be implemented by, for example, a data selector, a multiplexer (MUX) or any other electronic component or combination of electronic components capable of data selection or data combination, and this disclosure is not limited in any particular way in this regard.

In the data compression circuit of this disclosure, the data-writing circuit 111 may be a single-input multiple-output component, the data-reading circuit 112 may be a multiple-input single-output component. The combination of the data-writing circuit 111 and the data-reading circuit 112 may allow simultaneous testing of a plurality of ICs 130 as well as a plurality of data channels or data transmission nodes in ICs 130. That may address a limitation of conventional techniques that one IC may occupy multiple test channels of an automatic IC tester. Thus, for the automatic IC tester which is expensive and has a limited number of test channels, the data compression circuit according to the embodiments of this disclosure may bring a multi-fold increase in the number of ICs that can be simultaneously tested, which may substantially increase the test efficiency and reduce the cost of a test.

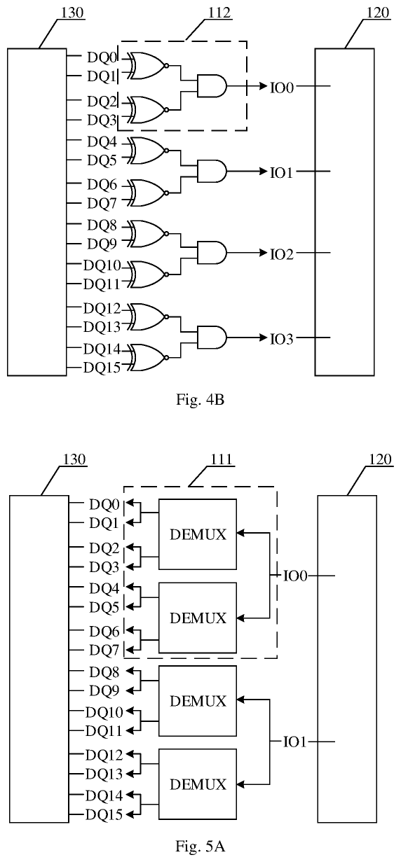

Referring to FIG. 4A, in some embodiments, the data-writing circuit 111 may include four first output interfaces and one first input interface, and the data-writing module may include one demultiplexer DEMUX. Therefore, in some embodiments, the data-writing circuit 111 may be a single-input four-output component capable of writing data at a compression ratio of 4:1. Accordingly, a one-pass test of an IC with 16 data channels DQ0, DQ1, DQ2, . . . , DQ15 may require four test channels IO0, IO1, IO2 and IO3 of an automatic IC tester 120. The sixteen data channels may be paired into eight data channel pairs. When receiving test data from the automatic IC tester 120 via a corresponding test channel and the first input interface coupled thereto, the demultiplexer DEMUX in the data-writing circuit 111 may divide the received test data into four data chunks and write them into the IC 130 via the four first output interfaces and the corresponding four data channels. Data that was written into the two data channels in each of the data channel pairs may be identical to facilitate a comparison on the corresponding data read by the data-reading circuit.

Referring to FIG. 4B, in some embodiments, the data-reading circuit 112 may include four second input interfaces and one second output interface, and the data-reading module may include two XNOR gates and one AND gate. Each of the XNOR gates may have two input terminals coupled to two corresponding second input interfaces. The two corresponding second input interfaces may be coupled to the respective data channels of a corresponding data channel pair. The AND gate may have input terminals coupled to output terminals of the XNOR gates and an output terminal coupled to the second output interface. In one example, when reading incoming data from the IC 130 via the second input interfaces and the corresponding data channels, each of the XNOR gates may compare the two data chunks coming from the corresponding data channel pair. In one example, a data channel pair may include the data channel DQ0 and the data channel DQ1. When the data chunks from the data channel DQ0 and the data channel DQ1 are identical to each other, the XNOR gate connected to them will output a high level. When both XNOR gates in the data-reading circuit 112 output high levels, the AND gate connected to the XNOR gates may also output a high level. In other words, when the AND gate outputs a high level, it may be determined that the data chunks from the corresponding data channel pairs are identical. That is, the data chunk from the data channel DQ0 is identical to the data chunk from the data channel DQ1, and the data chunk from the data channel DQ2 is identical to the data chunk from the data channel DQ3. Therefore, when the test result for the test channel IO0 is a high level, the corresponding four data channels DQ0, DQ1, DQ2 and DQ3 will be determined as normal (“PASS”). Otherwise, the determination will be abnormal (“FAIL”). When the test results for the four test channels IO0, IO1, IO2 and IO3 are all high levels, it can be determined that the IC 130 passes the test.

Since the data compression circuit according to some embodiments is capable of compressing data at a ratio of 4:1, a test of an IC with 16 data channels may only require 4 test channels. In one example, by using the data compression circuit of this embodiment, an automatic IC tester with 1024 test channels may simultaneously test 256 such 16-channel ICs. Therefore, the number of ICs that can be simultaneously tested may be substantially increased, which results in an improvement in the test efficiency and a reduction on the cost of a test.

Referring to FIG. 5A, in some embodiments, the data-writing circuit 111 may include eight first output interfaces and one first input interface, and the data-writing module may include two demultiplexers DEMUX. Therefore, in some embodiments, the data-writing circuit 111 may be a single-input eight-output component capable of writing data at a compression ratio of 8:1. Accordingly, a one-pass test of an IC with 16 data channels DQ0, DQ1, DQ2, . . . , DQ15 may require two test channels IO0 and IO1 of an automatic IC tester.

Referring to FIG. 5B, in some embodiments, the data-reading circuit 112 may include eight second input interfaces and one second output interface, and the data-reading module may include four XNOR gates and one AND gate. The AND gate may have input terminals coupled to output terminals of the four XNOR gates and an output terminal coupled to the test channel IO0 or IO1 via the second output interface.

The data compression circuit according to these embodiments may operate in a similar way to those of previous embodiments, and a detailed description thereof is thus omitted here for the sake of clarity and brevity.

Since the data compression circuit according to these embodiments is capable of compressing data at a ratio of 8:1, a test of an IC with 16 data channels may only require 2 test channels. In one example, by using the data compression circuit of these embodiments, an automatic IC tester with 1024 test channels may simultaneously test 512 such 16-channel ICs. Therefore, the number of ICs that can be simultaneously tested may be substantially increased, which results in an improvement in the test efficiency and a reduction on the cost of a test.

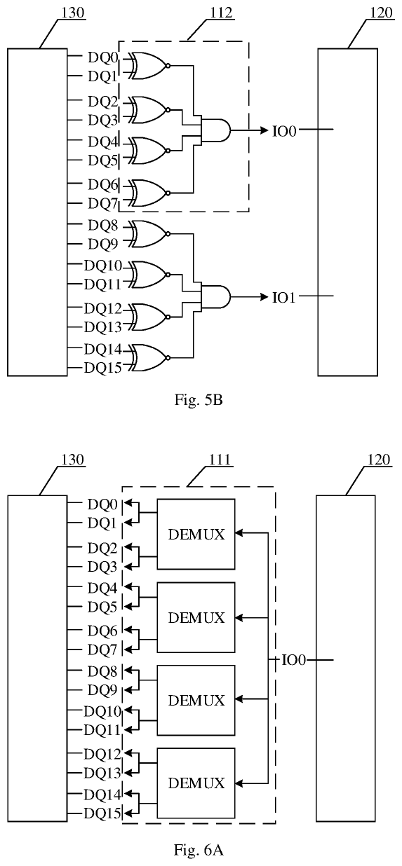

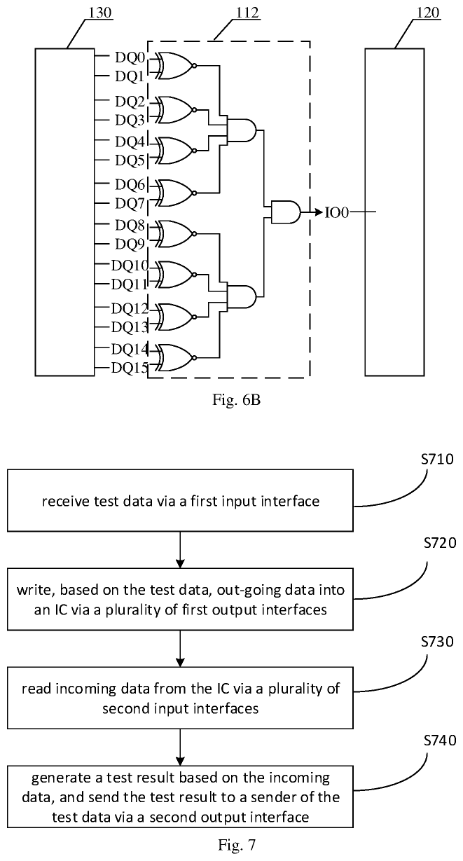

Referring to FIG. 6A, in some embodiments, the data-writing circuit 111 may include sixteen first output interfaces and one first input interface, and the data-writing module may include four demultiplexers DEMUX. Therefore, in some embodiments, the data-writing circuit may be a single-input sixteen-output component capable of writing data at a compression ratio of 16:1. Accordingly, a one-pass test of an IC with 16 data channels DQ0, DQ1, DQ2, . . . , DQ15 may require one test channel IO0 of an automatic IC tester.

Referring to FIG. 6B, in some embodiments, the data-reading circuit 112 may include sixteen second input interfaces and one second output interface, and the data-reading module may include eight XNOR gates and three AND gates. Two of the AND gates may have input terminals coupled to output terminals of the eight XNOR gates, and the remaining one AND gate may have input terminals coupled to output terminals of said two AND gates and an output terminal coupled to the test channel IO0 via the second output interface.

The data compression circuit according to these embodiments may operate in a similar way to those of previous embodiments, and a detailed description thereof is thus omitted here for the sake of clarity and brevity.

Since the data compression circuit according to these embodiments is capable of compressing data at a ratio of 16:1, a test of an IC with 16 data channels may only require one test channel. In one example, by using the data compression circuit of these embodiments, an automatic IC tester with 1024 test channels may simultaneously test 1024 such 16-channel ICs. Therefore, the number of ICs that can be simultaneously tested may be substantially increased, which results in an improvement in the test efficiency and a reduction on the cost of a test.

This disclosure further presents a memory device including an IC with a plurality of data channels and a data compression circuit according to any one of the aforementioned embodiments. The plurality of data channels of the IC may be coupled to the plurality of second input interfaces and the plurality of first output interfaces of the data compression circuit. In a test of the memory device, the data compression circuit within the memory device may assist an automatic IC tester to test the ICs in the memory device. The test may be carried out in a same manner as those discussed above, and a detailed description thereof is thus omitted here for the sake of clarity and brevity. The memory device according to this embodiment may be a dynamic random access memory (DRAM) or any other IC-based memory device, and this disclosure is not limited in any particular way in this regard.

This disclosure further presents an IC test device including a plurality of test channels and the data compression circuit according to any of the aforementioned embodiments. The plurality of test channels may be coupled to the first input interface and second output interface of the data compression circuit. In some embodiments, as a functional module of the IC test device, the data compression circuit may assist the test of the ICs with compressed data, which may increase the number of ICs that can be simultaneously tested. The test can be carried out in a same manner as those discussed above, and a detailed description thereof is thus omitted here for the sake of clarity and brevity.

Based on the data compression circuits, the memory device and the IC test device according to the above embodiments, this disclosure further presents an IC test method including the following steps S710 through S740, as shown in FIG. 7.

In step S710, test data may be received via a first input interface.

In a data-writing phase, the data compression circuit may first receive the test data for an IC via the first input interface. The test data may be directly received from an automatic IC tester which may additionally provide a desired test result associated with the test data for a subsequent comparison.

In step S720, based on the test data, out-going data may be written into the IC via the plurality of first output interfaces.

The plurality of first output interfaces in the data compression circuit may be coupled to respective data channels of the IC, or respective data transmission nodes in the IC, or any locations of the IC other than the data channels and the data transmission nodes. Based on the test data, multiple data chunks can be simultaneously written into the IC via the first output interfaces.

In step S730, incoming data may be read from the IC via the plurality of second input interfaces.

In a data-reading phase, the data compression circuit may read incoming data from the IC via the plurality of second input interfaces. Likewise, the second output interfaces may be coupled to the respective data channels of the IC, or the respective data transmission nodes therein, or any locations of the IC other than the data channels and the data transmission nodes.

In step S740, a test result is generated based on the incoming data and sent to a sender of the test data via the second output interface.

Upon the completion of the data-reading phase, the data compression circuit may generate the test result based on the incoming data and send the test result to the sender of the test data via the second output interface. The sender of the test data may be the automatic IC tester. The test result may serve as a basis for determining whether the IC has passed the test.

The IC test method according to this embodiment may deploy a data compression circuit according to any one of the aforementioned embodiments. The procedures of a test may be the same as those disclosed in the aforementioned embodiments, and a detailed description thereof is thus omitted here for the sake of clarity and brevity.

The IC test method according to this embodiment may bring a multi-fold increase in the number of ICs that can be simultaneously tested, which may substantially increase the test efficiency and reduce the cost of a test.

Other embodiments of the present invention will be apparent to those skilled in the art by considering the specification and practicing the invention disclosed herein. Accordingly, this present invention is intended to cover all and any variations, uses, or adaptations of the present invention which follow, in general, the principles thereof and include such departures from the present invention as come within common knowledge or customary practice within the art to which the invention pertains. It is also intended that the specification and examples be considered as exemplary only, with true scope and spirit of the present invention being indicated by the appended claims.

1. An electronic device, comprising:
an integrated circuit (IC); and
a data compression circuit for testing the IC, the data compression circuit comprising a data-writing circuit and a data-reading circuit,
wherein the data-writing circuit comprises:
a first input interface for receiving test data;
a plurality of first output interfaces coupled to the IC; and
a data-writing module configured to write first data derived from the test data into the IC via the plurality of first output interfaces,
and wherein the data-reading circuit comprises:
a plurality of second input interfaces coupled to the IC;
a second output interface coupled to a sender of the test data; and
a data-reading module configured to read second data from the IC via the plurality of second input interfaces, generate a test result based on the second data, and send the test result to the sender of the test data via the second output interface.

2. The device of claim 1, wherein the plurality of first output interfaces and the plurality of second input interfaces are both connected to a plurality of data channels of the IC.

3. The device of claim 2, wherein the plurality of data channels comprise two data channels,
wherein the data-writing module is configured to write the first data into the two data channels via the first output interfaces, and the first data written into each of the two data channels are identical,
wherein the data-reading module is configured to read the second data from the two data channels via the second input interfaces and determine whether the second data read from the two data channels are identical.

4. The device of claim 3, wherein the data-reading module comprises:
a plurality of XNOR gates each having input terminals coupled to the plurality of second input interfaces; and
one or more AND gates each having input terminals coupled to output terminals of the plurality of XNOR gates and an output terminal coupled to the second output interface.

5. The device of claim 4, wherein the test result is pass if an output signal of the one or more AND gates is a high level.

6. The device of claim 3, wherein the test result is fail if the second data read from the two data channels are different.

7. The device of claim 1, wherein a number of the first output interfaces is equal to a number of the second input interfaces.

8. The device of claim 1, wherein the data-writing module comprises one or more demultiplexers.

9. The device of claim 1, wherein the data-reading module comprises one or more multiplexers.

10. The device of claim 1, wherein the IC is a dynamic random access memory (DRAM).

11. An integrated circuit (IC) testing method, comprising:
receiving test data via a first input interface;
writing first data derived from the test data into an IC via a plurality of first output interfaces;
reading second data from the IC via a plurality of second input interfaces;
generating a test result based on the second data; and
sending the test result to a sender of the test data via a second output interface.

12. The method of claim 11, wherein the plurality of first output interfaces and the plurality of second input interfaces are both connected to a plurality of data channels of the IC.

13. The method of claim 12, wherein the plurality of data channels comprise two data channels,
wherein writing first data derived from the test data into an IC via a plurality of first output interfaces comprises:
writing the first data into the two data channels via the first output interfaces, wherein the first data written into each of the two data channels are identical,
wherein reading second data from the IC via a plurality of second input interfaces comprises:
reading the second data from the two data channels via the second input interfaces; and
determining whether the second data read from the two data channels are identical.

14. The method of claim 13, wherein the plurality of second input interfaces are coupled to input terminals of a plurality of XNOR gates, the second output interface is coupled to an output terminal of one or more AND gates,
and wherein output terminals of the plurality of the XNOR gates are coupled to input terminals of the one or more AND gates.

15. The method of claim 14, wherein the test result is pass if an output signal of the one or more AND gates is a high level.

16. The method of claim 13, wherein the test result is fail if the second data read from the two data channels are different.

17. The method of claim 11, wherein a number of the first output interfaces is equal to a number of the second input interfaces.

18. The method of claim 11, wherein the first input interface is coupled to an input of one or more demultiplexers, and the plurality of first output interfaces are coupled to outputs of the one or more demultiplexers.

19. The method of claim 11, wherein the plurality of second input interfaces are coupled to inputs of one or more multiplexers, and the second output interface is coupled to an output of the one or more multiplexers.

20. The method of claim 11, wherein the IC is a dynamic random access memory (DRAM).
